(19) United States
(12) Patent Application Publication
(10) Pub. No.: US 2010/0051934 A1
(43) Pub. Date: Mar. 4, 2010

(54) THIN FILM TRANSISTOR ARRAY PANEL AND METHOD OF MANUFACTURING THE SAME

(76) Inventors: Jong-Hyun Choung, Hwaseong-si (KR); Bong-Kyun Kim, Incheon-si (KR); Byeong-Jin Lee, Yongin-si (KR); Sun-Young Hong, Yongin-si (KR); Pil-Sang Yun, Seoul (KR); Hong-Sick Park, Suwon-si (KR); Dong-Ju Yang, Seoul (KR); Young-Joo Choi, Jeollanam-do (KR); Nam-Seok Suh, Yongin-si (KR)

Correspondence Address: Haynes and Boone, LLP;IP Section, 2323 Victory Avenue, SUITE 700, Dallas, TX, 75219, US

(21) Appl. No.: 12/504,483

(22) Filed: Jul. 16, 2009

(30) Foreign Application Priority Data
Aug. 26, 2008 (KR) 10-2008-0083184

(51) Int. Cl. H01L 29/786; H01L 21/336

(52) U.S. Cl. 257/43; 438/104; 257/E29.296; 257/E21.411; 438/694; 438/669

(57) ABSTRACT

A thin film transistor array panel and a method of manufacturing the same are provided according to one or more embodiments. In an embodiment, a method includes: forming a gate line on an insulation substrate; stacking a gate insulating layer, an oxide semiconductor layer, a first barrier layer, and a first copper layer on the gate line; performing a photolithography process on the oxide semiconductor layer, the first barrier layer, and the first copper layer and forming a data line including a source electrode, a drain electrode, and an oxide semiconductor pattern; forming a passivation layer having the contact hole that exposes the drain electrode on the data line and the drain electrode; and forming a pixel electrode that is connected to the drain electrode through the contact hole on the passivation layer, wherein the forming of a data line, a drain electrode, and an oxide semiconductor pattern includes wet etching the first copper layer and then wet etching the first barrier layer and the oxide semiconductor layer.

### CROSS-REFERENCE TO RELATED APPLICATION

This application claims priority to and the benefit of Korean Patent Application No. 10-2008-0083184 filed in the Korean Intellectual Property Office on Aug. 26, 2008, the entire contents of which are incorporated herein by reference.

### BACKGROUND

(a) Technical Field

Embodiments of the present invention generally relate to a thin film transistor array panel and a method of manufacturing the same.

(b) Description of the Related Art

A thin film transistor (TFT) array panel is used as a circuit board for independently driving each pixel in a liquid crystal display, an organic electro-luminescent (EL) display device, etc. The TFT array panel has a scanning signal wire that transfers a scanning signal or a gate wire and an image signal line that transfers an image signal or a data wire, and includes a TFT that is connected to the gate wire and the data wire.

Due to an increase in size and definition of liquid crystal displays, resistance of a metal wire such as a gate wire and/or a data wire that are formed in the TFT array panel is increased, and thus RC delay occurs. As a method of reducing resistance of the metal wire, a method of using copper, which is a low resistance metal, has been developed.

Research has been performed for applying, as a semiconductor of the TFT, an oxide semiconductor having a great on-off current ratio of 105-107 and having mobility 10-100 times greater than that of amorphous silicon, which has been generally used as the semiconductor of the TFT. For the oxide semiconductor, because a small quantity of photoelectrons is generated due to visible light, a small quantity of leakage current is also generated due to visible light.

### SUMMARY

When using an oxide semiconductor as a semiconductor of a TFT and applying copper as a wiring material, etching characteristics thereof are different from those of existing amorphous silicon or wiring material, and thus an existing manufacturing method may not be used.

Embodiments of the present invention provide a thin film transistor array panel and a method of manufacturing the same that may simplify a manufacturing method when manufacturing a TFT array panel by using an oxide semiconductor as a semiconductor of a TFT and applying copper as a wiring material.

An exemplary embodiment of the present invention provides a TFT array panel including: an insulation substrate; a gate line that is formed on the insulation substrate and that includes a gate electrode; a gate insulating layer that is formed on the gate line; an oxide semiconductor that is formed on the gate insulating layer; a data line that is formed on the oxide semiconductor and that includes a source electrode; a drain electrode that is formed on the oxide semiconductor and that is opposite to the source electrode at a position corresponding to the gate electrode; a passivation layer that is formed on the data line and the drain electrode and that has a contact hole that exposes the drain electrode; and a pixel electrode that is formed on the passivation layer and that is connected to the drain electrode through the contact hole, wherein the data line and the drain electrode include a first barrier layer and a first copper layer that is formed on the first barrier layer and the data line and the drain electrode are disposed within an outer line of the oxide semiconductor.

The first barrier layer may have an exposed upper surface by escaping from the first copper layer in a portion in which the source electrode and the drain electrode are opposite to each other.

The first barrier layer may include titanium (Ti), molybdenum (Mo), molybdenum niobium (MoNb), and/or a molybdenum alloy.

The gate line may include a second barrier layer and a second copper layer on the second barrier layer.

The second barrier layer may include titanium (Ti), molybdenum (Mo), molybdenum niobium (MoNb), and/or a molybdenum alloy.

A thickness of the first copper layer and the second copper layer may be about 2000-30,000 \acute{Å}.

A thickness of the oxide semiconductor may be about 300-2000 \acute{Å}, and a thickness of the first barrier layer may be about 100-400 \acute{Å}.

The oxide semiconductor may include an oxide of Zn, In, Ga, and Sn, or a mixture thereof.

Another embodiment of the present invention provides a method of manufacturing a TFT array panel, including: forming a gate line on an insulation substrate; stacking a gate insulating layer, an oxide semiconductor layer, a first barrier layer, and a first copper layer on the gate line; performing a photolithography process of the oxide semiconductor layer, the first barrier layer, and the first copper layer and forming a data line including a source electrode, a drain electrode, and an oxide semiconductor pattern; forming a passivation layer having a contact hole that exposes the drain electrode on the data line and the drain electrode; and forming a pixel electrode that is connected to the drain electrode through the contact hole on the passivation layer, wherein the forming of a data line, a drain electrode, and an oxide semiconductor pattern includes wet etching the first copper layer and then wet etching the first barrier layer and the oxide semiconductor layer.

The forming of a data line, a drain electrode, and an oxide semiconductor pattern may include forming a first photosensitive film pattern including a first portion and a second portion having a smaller thickness than the first portion on the first copper layer; wet etching the first copper layer using the first photosensitive film pattern as a mask; wet etching the first barrier layer and the oxide semiconductor layer using the first photosensitive film pattern as a mask; forming a second photosensitive film pattern by removing the second portion by etching back the first photosensitive film pattern; wet etching the first copper layer that is exposed by removing the second portion; dry etching the first barrier layer that is exposed by wet etching the first copper layer; and removing the second photosensitive film pattern.

Wet etching of the first copper layer may be performed using a non-hydro-peroxide type of etchant including water, nitric acid, and ammonium persulfate (APS), or using a hydro-peroxide type of etchant including H₂O and H₂O₂ as an essential element and including an acid and an additive.

Wet etching of the first barrier layer and the oxide semiconductor layer may be performed using an etchant including HF.

The etchant including HF may include water and HF with a concentration ratio of 1000:1 to 20:1.

Wet etching of the first barrier layer and the oxide semiconductor layer may be performed for 10-90 seconds.

In the stacking of a gate insulating layer, an oxide semiconductor layer, a first barrier layer, and a first copper layer on the gate line, the oxide semiconductor layer may be deposited by flowing Ar and O₂ with a flux of 30-l00 sccm and 10-90 sccm, respectively, applying a deposition pressure of 0.12-0.5 pa, and supplying power of 1-3 KW.

In the dry etching of the first barrier layer, Cl2 and BCl3 may be used as etching gases.

The dry etching of the first barrier layer may be performed by flowing Cl2 and BCl3 with a flux of 20-100 sccm and 50-200 sccm, respectively, and supplying source power of 500-1500 W and bias power of 200-500 W.

The first barrier layer may include titanium (Ti).

The forming of a gate line on the insulation substrate may include: forming a second barrier layer; forming a second copper layer on the second barrier layer; forming a third photosensitive film pattern on the second copper layer; wet etching the second copper layer using the third photosensitive film pattern as a mask; and wet etching the second barrier layer using the third photosensitive film pattern as a mask.

Wet etching of the second copper layer may be performed using a non-hydro-peroxide type of etchant including water, nitric acid, and APS, or using a hydro-peroxide type of etchant including H₂O and H₂O₂ as an essential element and including an acid and an additive, and wet etching of the second barrier layer may be performed using a HF aqueous solution.

As described above, according to an exemplary embodiment of the present invention, after wet etching a copper layer, both a barrier layer and an oxide semiconductor layer may be wet-etched and thus a manufacturing process may be simplified and manufacturing costs may be reduced.

Furthermore, because both the copper layer and the barrier layer may be wet-etched, the profile of wiring may be improved and the manufacturing process may be simplified.

### BRIEF DESCRIPTION OF THE DRAWINGS

FIG. 1 is a layout view of a liquid crystal display according to an exemplary embodiment of the present invention.

FIG. 2 is a cross-sectional view of the liquid crystal display taken along line II-II′ of FIG. 1.

FIGS. 3 to 6 are cross-sectional views respectively illustrating an intermediate step of a method of manufacturing a TFT array panel according to an exemplary embodiment of the present invention.

FIG. 7 is an electron microscope picture of both a copper layer and a barrier layer after patterning with wet etching when manufacturing a TFT array panel according to an exemplary embodiment of the present invention.

FIGS. 8 to 11 are electron microscope pictures of a barrier layer and an oxide semiconductor layer after patterning with wet etching at various conditions.

### DETAILED DESCRIPTION

Embodiments of the present invention will be described more fully hereinafter with reference to the accompanying drawings, in which exemplary embodiments of the invention are shown. As those skilled in the art would realize, the described embodiments may be modified in various different ways, all without departing from the spirit or scope of the present disclosure.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element, or intervening elements may also be present. In contrast, when an element is referred to as being “directly on” another element, there are no intervening elements present.

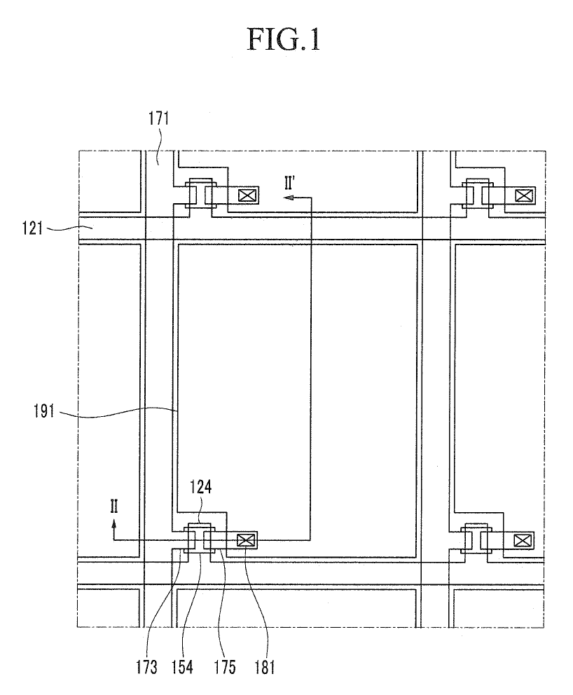

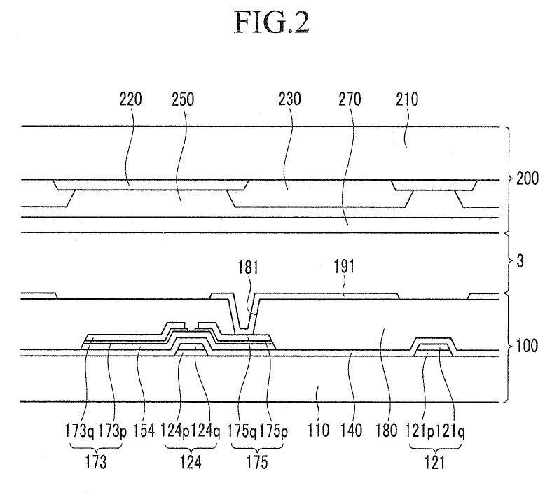

A liquid crystal display according to an exemplary embodiment of the present invention is described in detail with reference to FIGS. 1 to 2.

FIG. 1 is a layout view of a liquid crystal display according to an exemplary embodiment of the present invention, and FIG. 2 is a cross-sectional view of the liquid crystal display taken along line Il-II of FIG. 1.

First, a TFT array panel 100 is described according to one or more embodiments.

As shown in FIGS. 1 and 2, gate lines 121 are formed on a transparent insulation substrate 110. The gate lines 121 transfer a gate signal and generally extend in a horizontal direction, and may include a wide end part for connecting to other layers or to an external driving circuit. The gate lines 121 include lower barrier layers 121p and 124p and upper copper layers 121q and 124q, and they may be formed with a sputtering or plating method. The barrier layers 121p and 124p may be formed with titanium (Ti), molybdenum (Mo), molybdenum niobium (MoNb), a molybdenum alloy, etc. A thickness of the copper layers 121q and 124q may be about 2000-30,000 \acute{Å}.

A gate insulating layer 140 is formed on the gate lines 121. The gate insulating layer 140 may be made of an inorganic insulating material such as silicon oxide or silicon nitride.

An oxide semiconductor 154 is formed on the gate insulating layer 140. The oxide semiconductor 154 may be made of an oxide of Zn, In, Ga, or Sn, or a mixture thereof such as ZnO, InGaZnO4, Zn—In—O, Zn—Sn—O, etc. The oxide semiconductor 154 may comprise, for example, an N-type or P-type oxide semiconductor containing a zinc oxide as a basic element and an oxide of at least one of elements In, Cu, Hf, Ga, Ge, Si, Zr, Ta, Sn, Sb, W, Mo, Te, Ce, Nb, Mn, Th, and P. Because the oxide semiconductor 154 has a great on-off current ratio of 105-107 and has mobility greater than, by about 10-100 times, amorphous silicon, a high performance TFT may be manufactured, and because the oxide semiconductor 154 has a band gap of 3.2-3.4 eV, visible light has a lesser leakage current. The oxide semiconductor 154 is formed long in a vertical direction, and may have a shape including a plurality of protruded portions. A thickness of the oxide semiconductor 154 may be about 300-2000 \acute{Å}.

A data line 171 having a source electrode 173 and a drain electrode 175 that is separated from and is opposite to the source electrode 173 are formed on the oxide semiconductor 154. The data line 171 transfers a data voltage and generally extends in a vertical direction to intersect the gate line 121, and may include a wide end part for connecting to other layers and to an external driving circuit. The data line 171 and the drain electrode 175 include lower barrier layers 173p and 175p and upper copper layers 173q and 175q. The lower barrier layers 173p and 175p may be formed with titanium (Ti), molybdenum (Mo), molybdenum niobium (MoNb), a molybdenum alloy, etc., and may have a thickness of about 100-400 \acute{Å}. A thickness of the upper copper layers 173q and 175q may be about 2000-30,000 \acute{Å}. All portions of the data line 171 and the drain electrode 175 are positioned within an outer line of the oxide semiconductor 154. The lower barrier layers 173p and 175p may have an exposed upper surface portion by escaping from the upper copper layers 173q and 175q in a portion in which the source electrode 173 and the drain electrode 175 are opposite to each other. This is because the upper copper layers 173q and 175q are patterned by wet etching and thus isotropic etching is performed, whereas the lower barrier layers 173p and 175p are patterned by dry etching and thus anisotropic etching is performed. In some portions, in addition to a portion in which the source electrode 173 and the drain electrode 175 are opposite to each other, an upper surface of the lower barrier layers 173p and 175p may be exposed by escaping from the upper copper layers 173q and 175q, however the exposed upper surface has the widest width in a portion in which the source electrode 173 and the drain electrode 175 are opposite to each other. This is because both the upper copper layers 173q and 175q and the lower barrier layers 173p and 175p are patterned by wet etching in some portions, in addition to a portion in which the source electrode 173 and the drain electrode 175 are opposite to each other.

A passivation layer 180 is formed on the data line 171 and the drain electrode 175. The passivation layer 180 may be made of an inorganic insulating material such as a silicon nitride and a silicon oxide, or an organic insulating material such as a resin. The passivation layer 180 may be formed with a double layer of an inorganic insulating material layer and an organic insulating material layer. The passivation layer 180 has a contact hole 181 that exposes the drain electrode 175.

A pixel electrode 191 is formed on the passivation layer 180. The pixel electrode 191 is connected to the drain electrode 175 through the contact hole 181. The pixel electrode 191 may be formed with a transparent conductive layer such as indium tin oxide (ITO) and indium zinc oxide (IZO), and may have a cutout pattern or a slit.

A storage electrode line for forming a storage capacitor by overlapping with the pixel electrode 191 may be further formed on the insulation substrate 110.

Next, a common electrode panel 200 is described according to one or more embodiments.

A light blocking member 220 is formed on an insulation substrate 210, and a color filter 230 is formed on the light blocking member 220. Most of the color filter 230 is positioned within a region that is partitioned by the light blocking member 220, and some color filter 230 thereof overlaps with the light blocking member 220. An overcoat 250 is formed on the light blocking member 220 and the color filter 230, and a common electrode 270 is formed on the overcoat 250. The overcoat 250 may be formed to provide a flat floor surface in the common electrode 270, and when the common electrode 270 has a cutout pattern (not shown), the overcoat 250 prevents the color filter 230 from being exposed to a liquid crystal layer 3 through the cutout pattern. The overcoat 250 may be omitted. The common electrode 270 may be formed with a transparent conductive layer such as ITO or IZO.

The liquid crystal layer 3 is formed between the common electrode panel 200 and the TFT array panel 100.

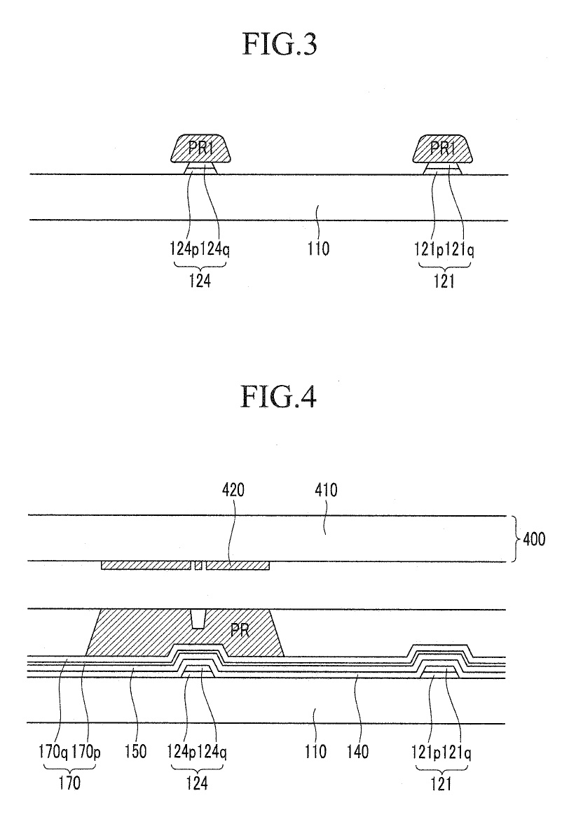

A method of manufacturing the TFT array panel of the liquid crystal display is described with reference to FIGS. 3 to 6 and the previously referred to FIGS. 1 and 2.

FIGS. 3 to 6 are cross-sectional views respectively illustrating an intermediate step of a method of manufacturing a TFT array panel according to an exemplary embodiment of the present invention.

First, as shown in FIG. 3 according to one or more embodiments, by continuously depositing a lower metal layer such as titanium and an upper metal layer consisting of copper on the substrate 110 and performing a photolithography process of both the lower metal layer and the upper metal layer, a gate line 121 including barrier layers 121p and 124p and copper layers 121q and 124q is formed. A photolithography process of the lower metal layer and the upper metal layer is performed by coating a photosensitive film on the upper metal layer and forming a photosensitive film pattern PR1 using a photolithography process and then wet etching the upper metal layer consisting of copper using the photosensitive film pattern PR1 as a mask. In this case, as an etchant, a non-hydro-peroxide type of etchant including 85% water, nitric acid, and Ammonium per sulfate (APS) may be used. The non-hydro-peroxide type of etchant etches a copper layer with a speed of about 4500 \acute{Å}/minute, and barely etches a barrier metal such as titanium. As a copper etchant, a hydro-peroxide type of etchant including H₂O and H₂O₂ as an essential element and including an acid such as a citric acid and an additive such as benzotriazole may be used. Next, a lower metal layer consisting of a barrier metal such as titanium is wet-etched using the photosensitive film pattern PR1 as a mask. In this case, as an etchant, a HF aqueous solution including water and HF with a concentration ratio of about 1000:1 to 20:1 may be used.

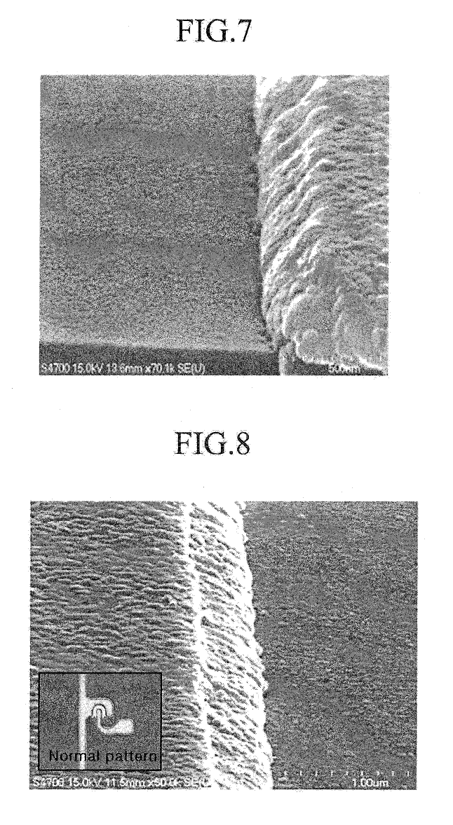

In this way, if both an upper metal layer consisting of copper and a lower metal layer consisting of a barrier metal such as titanium are patterned by wet etching, a process may be simplified, a clearance ratio may be improved, and a waterfall failure may be prevented, compared with an existing case of mixing wet etching and dry etching. That is, when mixing wet etching and dry etching, in consideration of an amount of undercut generated due to isotropic etching of the wet etching, an etch-back process of a photosensitive film pattern is required after the wet etching, and for this purpose, a photosensitive film should be thick. However, when only wet etching is used, an etch-back process of a photosensitive film pattern is unnecessary, and thus the process is simplified. Further, when mixing wet etching and dry etching, a lower metal layer consisting of a barrier metal protrudes and the aperture ratio is thus deteriorated and a waterfall failure may be caused. However, when using only wet etching, these problems do not occur. Referring to FIG. 7, according to an exemplary embodiment of the present invention, when both the copper layers 121q and 124q and the barrier layer 121p and 124p are patterned with wet etching, it can be seen that a gate line 121 having a clean profile in which the barrier layers 121p and 124p do not protrude is formed without damaging the substrate 110.

Next, as shown in the embodiment of FIG. 4, the gate insulating layer 140, an oxide semiconductor layer 150, a lower metal layer 170p consisting of a barrier metal such as titanium, and an upper metal layer 170q consisting of copper are continuously stacked on the gate line 121. In this embodiment, the oxide semiconductor layer 150 may be deposited with a thickness of about 300-2000 \acute{Å} by flowing Ar and O₂ with a flux of 30-100 sccm and 10-90 sccm, respectively, applying a deposition pressure of 0.12-0.5 pa, and supplying power of 1-3 KW.

Next, by coating a photosensitive film PR on the upper metal layer 170q and using a half-tone mask 400, exposure is performed. In this case, the half-tone mask 400 includes a transparent substrate 410 and a light blocking layer 420, wherein the light blocking layer 420 has a slit region. A slit region, i.e., a transflective region, of the half-tone mask 400 is disposed at a position corresponding to the center of the gate electrode 124. A light blocking region is disposed at a position at which the data line 171 and the drain electrode 175 are to be formed, and a transmission region is disposed at the remaining portion. In the present exemplary embodiment, a case of using a positive photosensitive film is illustrated, but when using a negative photosensitive film, positions of the transmission region and the light blocking region are reversed. Also, a transflective region of the half-tone mask 400 may be formed using a translucent film instead of a slit.

Next, as shown in FIG. 5, by developing the exposed photosensitive film, a photosensitive film pattern PR2 is formed, and an upper metal layer 170q consisting of copper is wet-etched using the photosensitive film pattern PR2 as a mask. In this embodiment, as an etchant, a non-hydro-peroxide type of etchant including 85% water, nitric acid, and APS may be used. As a copper etchant, a hydro-peroxide type of etchant including H₂O and H₂O₂ as an essential element and including an acid such as citric acid and an additive such as benzotriazole may be used.

Next, by wet etching both the exposed lower metal layer 170p and the oxide semiconductor layer 150, the data line 171 to which the source electrode 173 and the drain electrode 175 are connected to and the lower oxide semiconductor 154 are formed. In this case, as an etchant, a HF aqueous solution including water and HF with a concentration ratio of about 1000:1 to 20:1 may be used, and wet etching may be performed for about 10-90 seconds.

Table 1 shows results, according to one or more embodiments, when IZO including Hf (hereinafter referred to as “XIZO”), which is an oxide semiconductor, a titanium layer, which is a barrier metal, and the copper layer are deposited, and the titanium layer and the XIZO are etched in a bundle under various conditions using a HF aqueous solution after patterning the copper layer.

TABLE 1

| XIZO | Ti | | | Drenching | | Lifting |
|---|---|---|---|---|---|---|
| thickness | thickness | Division | HF dilution | time period | Viewing | degree of |
| (\acute{Å}) | (\acute{Å}) | number | ratio | (second) | test | Cu |
| 700 | 300 | 1 | 1:300 | 110 | lifting of | About |
| | | | | | Cu | 90% |
| | | 2 | 1:400 | 90 | lifting of | About |
| | | | | | Cu | 80% |
| | | 3 | 1:400 | 60 | lifting of | About 5% |
| | | | | | Cu | |
| | | 4 | 1:400 | 30 | Good | Normal |
| 1000 | | 5 | 1:300 | 110 | lifting of | About |
| | | | | | Cu | 100% |
| | | 6 | 1:400 | 90 | lifting of | About |
| | | | | | Cu | 30% |
| | | 7 | 1:400 | 60 | Good | Normal |
| | | 8 | 1:400 | 30 | no etching | |

In an experiment of Table 1 according to an embodiment, XIZO was deposited by flowing Ar and O₂ with a ratio of 50:10.

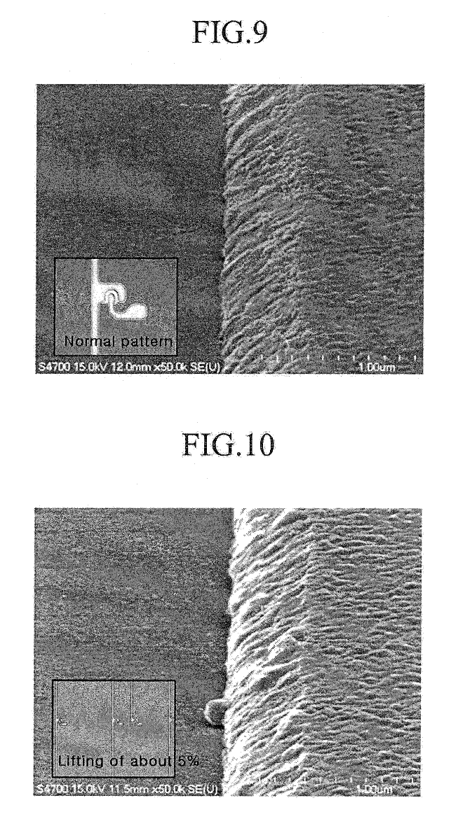

In Table 1, when the thickness of the XIZO layer is 700 \acute{Å} and the thickness of the titanium layer is 300 \acute{Å}, by etching the titanium layer and the XIZO layer by drenching for 30 seconds in a HF aqueous solution that is diluted at 1:400, or when the thickness of the XIZO layer is 1000 \acute{Å} and the thickness of the titanium layer is 300 \acute{Å}, by etching the titanium layer and the XIZO layer by drenching for 60 seconds in a HF aqueous solution that is diluted at 1:400, it can be seen that the XIZO layer and the titanium layer are well-etched without lifting of the copper layer, as shown in FIGS. 8 and 9. FIG. 8 is an electron microscope picture of the XIZO layer and the titanium layer that are etched by drenching for 30 seconds in a HF aqueous solution that is diluted at 1:400 when the thickness of the XIZO layer is 700 \acute{Å} and the thickness of the titanium layer is 300 \acute{Å}, and FIG. 9 is an electron microscope picture of the XIZO layer and the titanium layer that are etched by drenching for 60 seconds in a HF aqueous solution that is diluted at 1:400 when the thickness of the XIZO layer is 1000 \acute{Å} and the thickness of the titanium layer is 300 \acute{Å}.

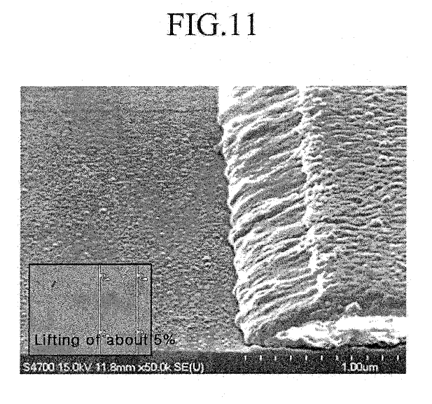

When the thickness of the XIZO layer is 700 \acute{Å} and the thickness of the titanium layer is 300 \acute{Å}, if the XIZO layer and the titanium layer are drenched for 60 seconds or more in a HF aqueous solution that is diluted at 1:400, or when the thickness of the XIZO layer is 1000 \acute{Å} and the thickness of the titanium layer is 300 \acute{Å}, if the XIZO layer and the titanium layer are drenched for 90 seconds or more in a HF aqueous solution that is diluted at 1:400, a copper layer is lifted, as shown in FIGS. 10 and 11. FIG. 10 is an electron microscope picture of the XIZO layer and the titanium layer that are etched by drenching for 60 seconds in a HF aqueous solution that is diluted at 1:400 when the thickness of the XIZO layer is 700 \acute{Å} and the thickness of the titanium layer is 300 \acute{Å}, and FIG. 11 is an electron microscope picture of the XIZO layer and the titanium layer that are etched by drenching for 90 seconds in a HF aqueous solution that is diluted at 1:400 when the thickness of the XIZO layer is 1000 \acute{Å} and the thickness of the titanium layer is 300 \acute{Å}.

When etching the XIZO layer and the titanium layer in a HF aqueous solution, it can be seen that in addition to a dilution ratio of a HF aqueous solution and a drenching time period, the thickness of the XIZO layer is a factor for determining lifting of a copper layer. This corresponds with a diagnosis that, because the etching speed by a HF aqueous solution is faster in a XIZO layer than in a titanium layer, when the XIZO layer is excessively etched, an undercut is deeply formed, and thus the copper layer is lifted. Therefore, by making the XIZO layer thick and the titanium layer thin, a margin of an etch condition that may etch the XIZO layer and the titanium layer while not causing lifting of the copper layer, may be increased. For example, if the thickness of the XIZO layer is set to 1000-2000 \acute{Å} and the thickness of the titanium layer is set to 100-200 \acute{Å}, even if the XIZO layer and the titanium layer are etched by drenching for 30-90 seconds in a HF aqueous solution at a dilution ratio of 1:400, the XIZO layer and the titanium layer may be etched in a bundle without lifting of the copper layer.

As described above according to one or more embodiments, after wet etching a copper layer, by wet etching both a barrier layer and an oxide semiconductor layer, the manufacturing process may be simplified and the manufacturing cost may be reduced.

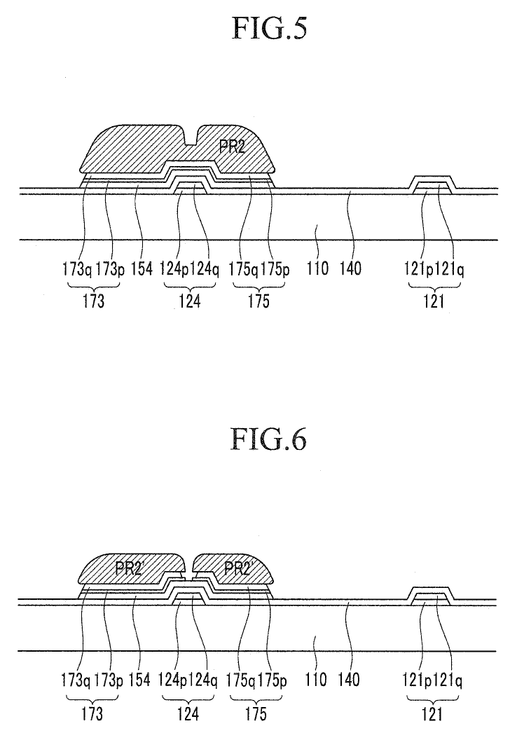

Next, as shown in FIG. 6, by etching back the photosensitive film pattern PR2, a photosensitive film pattern PR2′ that exposes the copper layers 173q and 175q between the source electrode 173 and the drain electrode 175 is formed.

Next, the copper layers 173q and 175q that are exposed using the photosensitive film pattern PR2′ as a mask are wet etched. In this embodiment, as an etchant, a non-hydro-peroxide type of etchant including 85% water, nitric acid, and APS may be used. As a copper etchant, a hydro-peroxide type of etchant including H₂O and H₂O₂ as an essential element and including an acid such as citric acid and an additive such as benzotriazole may be used.

Next, the exposed barrier layers 173p and 175p are dry-etched using the photosensitive film pattern PR2′ as a mask. In this embodiment, dry etching may be performed by flowing Cl12 and BCl3 with a flux of 20-100 sccm and 50-200 sccm, respectively, supplying source power of 500-1500 W and bias power of 200-500 W, and applying a gas pressure to 10 mT.

Thereby, the barrier layers 173p and 175p may have an exposed upper surface portion by escaping from the copper layers 173q and 175q in a portion in which the source electrode 173 and the drain electrode 175 are opposite to each other. However, by wet etching of the copper layers 173q and 175q, then additionally etching back the photosensitive film pattern PR2′, removing a photosensitive film pattern portion that overhangs on the copper layers 173q and 175q, and then dry-etching the barrier layers 173p and 175p, the barrier layers 173p and 175p may be prevented from being exposed by escaping from the copper layers 173q and 175q.

Next, as shown in FIG. 2, by removing the photosensitive film pattern PR2′, stacking the passivation layer 180, and performing a photolithography process, the contact hole 181 is formed.

Next, by forming a transparent conductive layer on the passivation layer 180 and performing a photolithography process, a pixel electrode 191 is formed.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A thin film transistor (TFT) array panel comprising:
an insulation substrate;
a gate line that is formed on the insulation substrate and that includes a gate electrode;
a gate insulating layer that is formed on the gate line;
an oxide semiconductor that is formed on the gate insulating layer;
a data line that is formed on the oxide semiconductor and that includes a source electrode;
a drain electrode that is formed on the oxide semiconductor and that is opposite to the source electrode at a position corresponding to the gate electrode;
a passivation layer that is formed on the data line and the drain electrode and that has a contact hole that exposes the drain electrode; and
a pixel electrode that is formed on the passivation layer and that is connected to the drain electrode through the contact hole,
wherein the data line and the drain electrode include a first barrier layer and a first copper layer that is formed on the first barrier layer, and the data line and the drain electrode are disposed within an outer line of the oxide semiconductor.

2. The TFT array panel of claim 1, wherein the first barrier layer has an exposed upper surface by escaping from the first copper layer in a portion in which the source electrode and the drain electrode are opposite to each other.

3. The TFT array panel of claim 2, wherein the first barrier layer comprises titanium (Ti), molybdenum (Mo), molybdenum niobium (MoNb), and/or a molybdenum alloy.

4. The TFT array panel of claim 3, wherein the gate line comprises a second barrier layer and a second copper layer on the second barrier layer.

5. The TFT array panel of claim 4, wherein the second barrier layer comprises titanium (Ti), molybdenum (Mo), molybdenum niobium (MoNb), and/or a molybdenum alloy.

6. The TFT array panel of claim 5, wherein a thickness of the first copper layer and the second copper layer is about 2000-30,000 \acute{Å}.

7. The TFT array panel of claim 6, wherein a thickness of the oxide semiconductor is about 300-2000 \acute{Å}, and a thickness of the first barrier layer is about 100-400 \acute{Å}.

8. The TFT array panel of claim 7, wherein the oxide semiconductor includes an oxide of Zn, In, Ga, Sn, or a mixture thereof.

9. The TFT array panel of claim 1, wherein the gate line comprises a second barrier layer and a second copper layer on the second barrier layer.

10. The TFT array panel of claim 9, wherein the second barrier layer comprises titanium (Ti), molybdenum (Mo), molybdenum niobium (MoNb), and/or a molybdenum alloy.

11. The TFT array panel of claim 1, wherein a thickness of the oxide semiconductor is about 300-2000 \acute{Å}, and a thickness of the first barrier layer is about 100-400 \acute{Å}.

12. A method of manufacturing a TFT array panel, comprising:
forming a gate line on an insulation substrate;
stacking a gate insulating layer, an oxide semiconductor layer, a first barrier layer, and a first copper layer on the gate line;
performing a photolithography process of the oxide semiconductor layer, the first barrier layer, and the first copper layer, and forming a data line including a source electrode, a drain electrode, and an oxide semiconductor pattern;
forming a passivation layer having a contact hole that exposes the drain electrode on the data line and the drain electrode; and
forming a pixel electrode that is connected to the drain electrode through the contact hole on the passivation layer,
wherein the forming of a data line, a drain electrode, and an oxide semiconductor pattern comprises wet etching the first copper layer and then wet etching the first barrier layer and the oxide semiconductor layer.

13. The method of claim 12, wherein the forming of a data line, a drain electrode, and an oxide semiconductor pattern comprises:
forming a first photosensitive film pattern including a first portion and a second portion having a smaller thickness than the first portion on the first copper layer;
wet etching the first copper layer using the first photosensitive film pattern as a mask;
wet etching the first barrier layer and the oxide semiconductor layer using the first photosensitive film pattern as a mask;
forming a second photosensitive film pattern by removing the second portion by etching back the first photosensitive film pattern;
wet etching the first copper layer that is exposed by removing the second portion;
dry etching the first barrier layer that is exposed by wet etching the first copper layer; and
removing the second photosensitive film pattern.

14. The method of claim 13, wherein wet etching of the first copper layer is performed using a non-hydro-peroxide type of etchant including water, nitric acid, and ammonium persulfate (APS), or using a hydro-peroxide type of etchant including H₂O and H₂O₂ as an essential element and including an acid and an additive.

15. The method of claim 14, wherein wet etching of the first barrier layer and the oxide semiconductor layer is performed using an etchant including HF.

16. The method of claim 15, wherein an etchant including HF includes water and HF with a concentration ratio of about 1000:1 to 20:1.

17. The method of claim 16, wherein wet etching of the first barrier layer and the oxide semiconductor layer is performed for about 10-90 seconds.

18. The method of claim 17, wherein the stacking of a gate insulating layer, an oxide semiconductor layer, a first barrier layer, and a first copper layer on the gate line comprises depositing the oxide semiconductor layer by flowing Ar and O₂ with a flux of 30-100 sccm and 10-90 sccm, respectively, applying a deposition pressure of 0.12-0.5 pa, and supplying power of 1-3 KW.

19. The method of claim 18, wherein the dry etching of the first barrier layer comprises using Cl2 and BCl3 as etching gases.

20. The method of claim 19, wherein the dry etching of the first barrier layer is performed by flowing Cl2 and BCl3 with a flux of 20-l00 sccm and 50-200 sccm, respectively, and supplying source power of 500-1500 W and bias power of 200-500 W.

21. The method of claim 20, wherein the first barrier layer comprises titanium (Ti).

22. The method of claim 20, wherein the forming of a gate line on the insulation substrate comprises:
forming a second barrier layer;
forming a second copper layer on the second barrier layer;
forming a third photosensitive film pattern on the second copper layer;
wet etching the second copper layer using the third photosensitive film pattern as a mask; and
wet etching the second barrier layer using the third photosensitive film pattern as a mask.

23. The method of claim 22, wherein the wet etching of the second copper layer is performed using a non-hydro-peroxide type of etchant including water, nitric acid, and APS, or using a hydro-peroxide type of etchant including H₂O and H₂O₂ as an essential element and including an acid and an additive, and wherein the wet etching of the second barrier layer is performed using a HF aqueous solution.

24. The method of claim 12, wherein the forming of a gate line on the insulation substrate comprises:
forming a second barrier layer;
forming a second copper layer on the second barrier layer;
forming a third photosensitive film pattern on the second copper layer;
wet etching the second copper layer using the third photosensitive film pattern as a mask; and
wet etching the second barrier layer using the third photosensitive film pattern as a mask.

25. The method of claim 24, wherein the wet etching of the second copper layer is performed using a non-hydro-peroxide type of etchant including water, nitric acid, and APS, or using a hydro-peroxide type of etchant including H₂O and H₂O₂ as an essential element and including an acid and an additive, and wherein the wet etching of the second barrier layer is performed using a HF aqueous solution.
